(19) United States
(12) Patent Application Publication
(10) Pub. No.: US 2003/0005881 A1
(43) Pub. Date: Jan. 9, 2003

(54) Method for forming contact plug of semiconductor device

(76) Inventor: Dong Suk Shin, Kyoungki-do (KR)

Correspondence Address: PILLSBURY WINTHROP, LLP, P.O. BOX 10500, MCLEAN, VA, 22102, US

(21) Appl. No.: 10/032,074

(22) Filed: Dec. 31, 2001

(30) Foreign Application Priority Data
Apr. 30, 2001 (KR) 2001-23402

(51) Int. Cl. C30B 23/00; C30B 25/00; C30B 28/12; C30B 28/14

(52) U.S. Cl. 117/97

(57) ABSTRACT

Disclosed is a method for forming a contact plug using a two-step epitaxial silicon growth process in which a first portion of epitaxial silicon is grown as single crystal silicon and the remainder of the contact plug is grown as polycrystalline or amorphous silicon. Preferably, the epitaxial silicon is grown using a LPCVD process at a temperature of 550° C. to 700° C. on a portion of the silicon substrate exposed at the bottom of a contact hole formed in an insulating layer, after the exposed portion of the silicon substrate has been cleaned and baked under H₂, with the epitaxial single crystal silicon covering the entire exposed portion of the silicon substrate, thereby reducing contact resistance and improving reliability.

### BACKGROUND OF THE INVENTION

1. Field of the Invention

The present invention relates to a method for forming plugs for a semiconductor device. More particularly, the invention relates to, a method for forming contact plugs using silicon epitaxial growth capable of preventing deterioration of device properties due to process temperature.

2. Description of the Related Art

As the integration degree of semiconductor devices is increased, the line width of circuit patterns is reduced. Accordingly, new technologies are being developed to improve device properties. In particular, new contact processes are being developed to increase device-operating efficiency.

When contact is unstable between upper and lower patterns or when contact resistance thereof is increased, device reliability is not obtained and there is difficulty in accomplishing fast operation although fine pattern line width is accomplished. Therefore, in a highly integrated device, for example, in a memory device of more than 256M, a self-aligned contact process is applied to accomplish stable contact of upper and lower patterns.

The conventional contact process comprises a first process for forming a contact hole to expose a part of a lower pattern, a second process for filling the contact hole with a conductive material to form a contact plug and a third process for forming an upper pattern in contact with the contact plug. Alternatively, the self-aligned contact process comprises a first process for forming a contact hole to expose predetermined word lines and silicon substrate regions between the word lines, a second process for depositing a conductive layer to fill the contact hole, a third process for polishing the conductive layer to form a contact plug, respectively, on the silicon substrate regions between the word lines, and a fourth process for forming an upper pattern in contact with each of the contact plugs.

In the self-aligned contact process, the contact hole has a larger size including a silicon substrate region of fine width between word lines, thereby accomplishing stable contact between upper and lower patterns. And, a plurality of contact plugs are simultaneously formed, thereby simplifying the processes.

Stable contact is obtained between upper and lower patterns by the self-aligned contact process, however, it is difficult to control an increase of contact resistance between upper and lower patterns. To be more detailed, polysilicon is generally used as a contact plug material, therefore, it is expected that contact resistance between silicon substrate and polysilicon is very low due to the similarity of the material. However, practically speaking, contact resistance between the silicon substrate and polysilicon is relatively high since natural oxide layers formed and residues created during the contact formation process are interposed between the silicon substrate and polysilicon and etching damage is generated on the surface of the silicon substrate. Hence, in a conventional contact plug formation process, the polysilicon is deposited immediately after the wet etching process that opens the contact holes in order to control the increase of contact resistance.

However, the increase of contact resistance according to decrease of contact area is still difficult to control since contact hole size has been markedly reduced as a result of the continuing reduction in unit cell area.

Therefore, in order to solve the problem of increased contact resistance resulting from the reduction in contact area, a method has been proposed in which a silicon epi layer, formed by selective epitaxial growth (“SEG”), is used to form a contact plug. The silicon epi layers have been used in shallow junction formation and isolation and have recently being used in contact plug formation.

Generally, a Low Pressure Chemical Vapor Deposition (“LPCVD”) has been used to grow the silicon epi layer. In the silicon epi layer growth using the LPCVD process, a mixed gas of dichlorosilane (“DSC”) (SiCl₂H₂), H₂ and HCl or a mixed gas of monosilane (“MS”) (SiH₄), H₂ and HCl is used as a reaction gas with PH₃used as a dopant.

However, the conventional LPCVD process for growing the silicon epi layer is accomplished at a high temperature of over 800° C., therefore, it is difficult to obtain stable device properties. That is, when the silicon epi layer is grown at a high temperature of over 800° C., deterioration of properties is caused since there is a significant and undesirable change in concentration of impurities doped in the junction area.

### SUMMARY OF THE INVENTION

Therefore, an object of the present invention is to provide a contact plug formation method wherein a contact plug is formed using silicon selective epitaxial growth and device properties are not deteriorated by the temperature of silicon epi layer growth.

In order to accomplish the above object, according to the present invention, a silicon epi layer is grown as a contact plug material in accordance with LPCVD process at a temperature of about 600 to 700° C. on a silicon substrate exposed by a contact hole formed in an insulating layer. The silicon epi layer is grown in single crystal silicon on a contact region with the silicon substrate and grown as polysilicon on the sidewalls of the contact hole.

According to the present invention, a silicon epi layer is grown as a contact plug material in accordance with the LPCVD process on a silicon substrate exposed by a contact hole formed in an insulating layer at a temperature of approximately 550 to 700° C. as single crystal silicon at the early growth stage and thereafter grown as amorphous silicon or polysilicon.

The contact plug formation method according to the present invention comprises: providing a silicon substrate which has an insulating layer having a contact hole formed therein; dry and wet cleaning the surface of the silicon substrate region exposed by the contact hole, successively; inserting the resultant silicon substrate into a LPCVD chamber; H₂ baking the surface of the silicon substrate region that has been exposed and cleaned; and growing a silicon epi layer on the exposed silicon substrate region at a temperature of approximately 550 to 700° C. in accordance with an in-situ LPCVD process so that a contact region with the silicon substrate and the other regions have different crystal structures.

In the above method, MS gas and H₂ gas or DCS and H₂ are used as reaction gas for growing silicon epi layer and PH₃ gas is used as dopant. The flow of MS gas or DCS gas is controlled to be approximately 100 to 500 sccm, and the flow of H₂ gas is controlled to be about 2,000 to 20,000 sccm and the flow of PH₃ gas is controlled to be around 100 to 300 sccm so that doping concentration of silicon epi layer becomes approximately 1×10¹⁹ to 10²¹ atoms/cc. And, the silicon epi layer is grown at a pressure of around 1 to 200 Torr. According to the present invention, dry and wet cleaning and H₂ baking are performed prior to growing the silicon epi layer.

The above objects, and other features and advantages of the present invention will become more apparent after reading the following detailed description when taken in conjunction with the drawings.

### BRIEF DESCRIPTION OF THE DRAWINGS

FIG. 1 is a cross-sectional view showing a silicon epi layer grown using a contact plug according to an embodiment of the present invention.

FIG. 2 is a cross-sectional view showing a silicon epi layer grown using a contact plug according to another embodiment of the present invention.

FIG. 3 is a cross-sectional view showing a silicon epi layer grown according to still another embodiment of the present invention.

FIG. 4 is a TEM photograph of semiconductor device illustrated in FIG. 3.

### DETAILED DESCRIPTION OF THE INVENTION

In a contact plug formation method using silicon epitaxial growth according to the present invention, use of HCl gas is omitted in the growth of silicon epi layer and a contact region with the silicon substrate and the other parts have different crystal structures to lower the growth temperature.

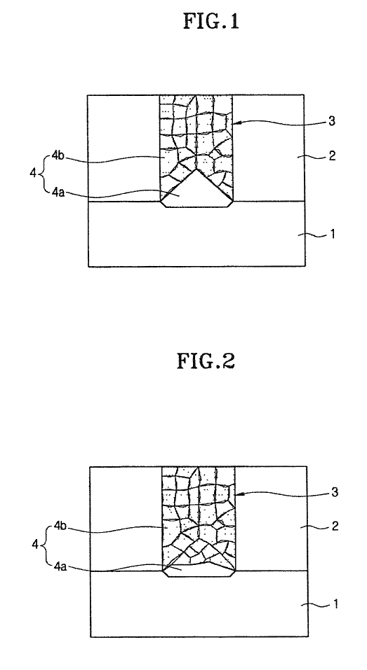

FIG. 1 is a cross-sectional view showing a silicon epi layer grown using a contact plug according to an embodiment of the present invention. As shown, a silicon epi layer 4 is grown as single crystal silicon 4a on a contact region with a silicon substrate 1 and grown as polysilicon 4b on the sidewalls of contact hole 3.

Here, the silicon epi layer is grown at a temperature of about 600 to 700° C. MS gas and H₂ gas are generally used as reaction gases to grow the silicon epi layer 4 and PH₃ gas is used as dopant. Instead of the MS gas, DCS gas may also be used. The flow of MS gas or DCS gas is controlled to be approximately 100 to 500 sccm, the flow of H₂ gas is controlled to be about 2,000 to 20,000 sccm, and the flow of PH₃ gas is controlled to be around 100 to 300 sccm so that the doping concentration of silicon epi layer becomes approximately 1×10¹⁹ to 10²¹ atoms/cc. And, the silicon epi layer 4 is grown at a pressure of about 1 to 200 Torr.

According to an embodiment of the present invention, it is possible to control the increase in contact resistance due to the reduction of contact area of the silicon substrate 1 and the silicon epi layer 4 since single crystal silicon is grown at a contact region with the silicon substrate 1. And, it is also possible to lower the growth temperature of the silicon epi layer 4 below the critical temperature, 700° C. In the present invention, a desirable growth temperature of approximately 600 to 700° C. can be used since only the contact region with the silicon substrate 1 is grown as single crystal silicon 4a.

And, according to the embodiment shown in FIG. 1, the single crystal silicon 4a is grown in the form a of a circular cone and the interface with polysilicon 4b is formed on the surface of the cone. Here, natural oxide layers are not generated on the interface since the interface is formed during the in-situ growth of both crystal morphologies.

Also, according to the present embodiment, dry cleaning using NF₃/O₂ plasma and wet cleaning using a mixed solution of Buffered Oxide Etch (“BOE”) and H₂SO₄ are performed respectively for around 20 to 30 seconds prior to growth of the silicon epi layer 4. Thereafter, H₂ baking is performed in the LPCVD chamber for growth of the silicon epi layer at a temperature of around 700 to 1,000° C. for approximately 60 to 300 seconds.

FIG. 2 is a cross-sectional view showing a silicon epi layer grown with a contact plug according to another embodiment of the present invention. As shown in the drawing, the silicon epi layer 4 is grown as single crystal silicon 4a at the early stage, that is, to 500 Å from the surface of silicon substrate 1 and after that, grown in amorphous silicon or desirably in polysilicon 4b.

Here, MS gas and H₂ gas are generally used as reaction gases for growth of the silicon epi layer 4 as shown in the prior embodiment. However, DSC gas may be used instead of the MS gas. And PH₃ gas is used as dopant. The flow of MS gas or DCS gas is controlled to be 100 to approximately 500 sccm, the flow of H₂ gas is controlled to be approximately 2,000 to 20,000 sccm and the flow of PH₃ gas is controlled to be approximately 100 to 300 sccm so that the doping concentration of the silicon epi layer is maintained at around 1×10¹⁹ to 10²¹ atoms/cc. And, the silicon epi layer 4 is grown at a pressure of about 1 to 200 Torr.

Processes are performed in a similar condition to the prior embodiment in the early stage of growth of the silicon epi layer 4. That is, the processes are performed in the stage of growth of single crystal silicon 4a and in 1 minute, desirably for 30 to 60 seconds. The growth of amorphous silicon or polysilicon 4b is performed at a temperature of 550 to 650° C., preferably around 550 to 610° C. And, according to the embodiment, dry cleaning using NF₃/O₂ plasma and wet cleaning using a mixed solution of BOE and H₂SO₄ are performed respectively for 20 to 30 seconds prior to growth of the silicon epi layer 4. Thereafter, H₂ baking is performed in the LPCVD chamber for growth of the silicon epi layer at a temperature of approximately 700 to 1,000° C. for around 60 to 300 seconds.

According to still another embodiment of the present invention, it is possible to control the contact resistance of the silicon substrate 1 and the silicon epi layer 4 due to the reduction of contact area and the lower process temperature.

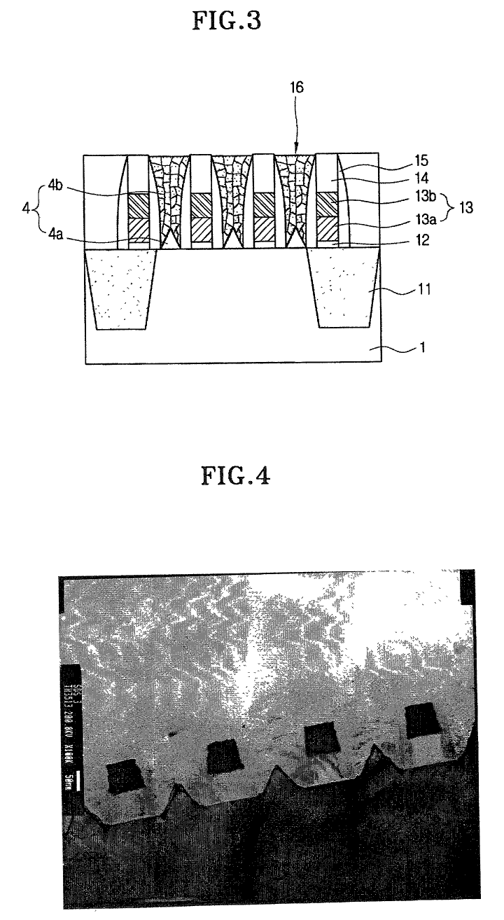

FIG. 3 is a cross-sectional view showing a contact plug comprising a silicon epi layer according to an embodiment of the present invention.

First, isolation layers 11, defining an active region, are formed on a silicon substrate 1 by conventional semiconductor fabrication methods and then a gate oxide layer 12, a gate electrode 13, comprising a polysilicon pattern 13a and a tungsten pattern 13b, and a hard mask layer 14 are formed on the active region of the silicon substrate 1. Thereafter, a nitride layer spacer 15 is formed on the sidewall of the stacked gate structure. Subsequently, an interlayer insulating layer 16 is deposited on the resultant structure and then the layer 16 is polished or etched back to expose the hard mask 14. A contact hole (not shown) is then formed to expose a portion of the stacked structure and a portion of the silicon substrate.

Next, in order to remove natural oxide layers and residues formed on the exposed silicon substrate 1 and to recover etching damage formed on the surface of substrate during the etching process to form a contact hole, dry cleaning using NF₃/O₂ plasma and wet cleaning using a mixed solution of BOE and H₂SO₄ are performed respectively for around 20 to 30 seconds. Thereafter, the resultant structure is inserted in a LPCVD chamber for growth of the silicon epi layer and H₂ baking is performed at a temperature of 700 to 1,000° C. for approximately 60 to 300 seconds.

Then, a silicon epi layer 4 is grown as contact plug material by silicon epitaxial growth using the LPCVD process on the contact plug formation region, that is, on the silicon substrate between the stacked structure. The silicon epi layer 4 is grown at a temperature of below 700° C., preferably, at a temperature of about 600 to 700° C. and grown in single crystal silicon 4a on the contact region with the silicon substrate 1 and grown in polysilicon 4b on the sidewall of contact hole. And, as described above, MS gas and H₂ gas are generally used as reaction gas to grow the silicon epi layer 4 and PH₃ gas is used as a dopant. However, instead of the MS gas, DCS gas may also be used. And, the silicon epi layer 4 is grown at a pressure of approximately 1 to 200 Torr.

Subsequently, Chemical Mechanical Polishing (“CMP”) or etch back is performed to the silicon epi layer 4, thereby forming a contact plug 16 comprising the silicon epi layer 4.

FIG. 4 is a TEM photograph of the device illustrated in FIG. 3. In the device shown in the TEM photograph, the silicon epi layer was grown at a temperature of 635° C., at a pressure of about 120 Torr. The flow of MS was controlled to about 200 sccm, the flow of H₂ was controlled to about 5000 sccm and the flow of PH₃ was controlled to about 300 sccm. As shown in the photograph, single crystal silicon 4a was grown in the form of circular cone on the contact region from the silicon substrate 1 and grown in polysilicon 4b as other parts.

As described above, according to the present invention, the silicon epi layer is grown as single crystal silicon on the contact region with silicon substrate and grown as polysilicon on other parts. Therefore, it is possible to grow the silicon epi layer at a temperature below 700° C. and to obtain a contact plug while improving interface properties with the silicon substrate.

In short, according to the present invention, a silicon epi layer is used as contact plug material and the growth temperature of the silicon epi layer is lowered below the critical temperature, i.e. below 700° C., by growing the silicon epi layer in different crystal morphologies in different regions of the contact hole.

Therefore, it is possible to prevent an increase in the contact resistance by forming a contact plug with the silicon epi layer. And, it is also possible to grow the silicon epi layer at a low temperature, thereby preventing deterioration of device properties due to excessive process temperature and preserve the thermal budget. As a result, the present invention can be advantageously applied to highly integrated and high-speed devices.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for forming a contact plug of a semiconductor device comprising:
forming an insulating layer on a silicon substrate;
opening a contact hole in the insulating layer, wherein a portion of the silicon substrate is exposed at a bottom of the contact hole; and
selectively growing a silicon epitaxial layer in the contact hole, wherein the selective epitaxial layer comprises a single crystal silicon portion, and a polycrystalline or amorphous silicon portion,
wherein the single crystal silicon portion comprises a substantially conical structure, a base of which substantially covers the exposed portion of the silicon substrate, and
further wherein the polycrystalline or amorphous silicon portion fills the remainder of the contact hole.

2. The method for forming a contact plug of a semiconductor device according to claim 1:
wherein the step of selectively growing a silicon epitaxial layer in the contact hole further comprises an LPCVD process wherein a reaction gas is a gas mixture comprising MS (SiH₄) and H₂ or a gas mixture comprising DSC (SiCl₂H₂) and H₂ and a dopant gas is PH₃.

3. The method for forming a contact plug of a semiconductor device according to claim 2:
wherein a flow of MS gas or DCS gas is controlled to be approximately 100 to 500 sccm and
a flow of H₂ gas is controlled to be approximately 2,000 to 20,000 sccm.

4. The method for forming a contact plug of a semiconductor device according to claim 2:
wherein a flow of PH₃ gas is controlled to obtain a phosphorus doping concentration in the silicon epitaxial layer between approximately 1×10¹⁹ to 10²¹ atoms/cc.

5. The method for forming a contact plug of a semiconductor device according to claim 1:
wherein the step of selectively growing the silicon epitaxial layer is conducted within a pressure range of approximately 1 to 200 Torr.

6. The method for forming a contact plug of a semiconductor device according to claim 1:
wherein the step of opening a contact hole in the insulating layer further comprises;
applying a dry cleaning process to the exposed portion of the silicon substrate;
applying a wet cleaning process to the exposed portion of the silicon substrate; and
baking the exposed portion of the silicon substrate in H₂;
these steps being completed before the step of selectively growing a silicon epitaxial layer in the contact hole.

7. The method for forming a contact plug of a semiconductor device according to claim 6:
wherein the step of applying a dry cleaning process further comprises treating the exposed portion of the silicon substrate using a NF₃/O₂ plasma for approximately 20 to 30 seconds.

8. The method for forming a contact plug of a semiconductor device according to claim 6:
wherein the step of applying a wet cleaning process further comprises treating the exposed portion of the silicon substrate using a mixed solution of BOE and H₂SO₄ for approximately 20 to 30 seconds.

9. The method for forming a contact plug of a semiconductor device according to claim 6:
wherein the step of baking further comprises treating the exposed portion of the silicon substrate using H₂ at a temperature between approximately 700 and 1,000° C. for approximately 60 to 300 seconds.

10. The method for forming a contact plug of a semiconductor device according to claim 1:
wherein the step of selectively growing a silicon epitaxial layer further comprises
growing the single crystal silicon portion using a LPCVD process at a temperature of approximately 600 to 700° C.; and then
growing the polycrystalline or amorphous silicon portion at a temperature of approximately 550 to 650° C.

11. The method for forming a contact plug of a semiconductor device according to claim 10:
wherein the step of selectively growing the silicon epitaxial layer further comprises a LPCVD process using a reaction gas comprising a gas mixture of MS (SiH₄) and H₂ or a gas mixture of DSC (SiCl₂H₂) and H₂ and a dopant gas comprising PH₃.

12. The method for forming a contact plug of a semiconductor device according to claim 11:
wherein a flow of MS gas or DCS gas is controlled to be approximately 100 to 500 sccm and
a flow of H₂ gas is controlled to be approximately 2,000 to 20,000 sccm.

13. The method for forming a contact plug of a semiconductor device according to claim 12:
wherein a flow of PH₃ gas is controlled to obtain a phosphorus doping concentration in the silicon epitaxial layer between approximately 1×10¹⁹ to 10²¹ atoms/cc.

14. The method for forming a contact plug of a semiconductor device according to claim 10:
wherein the step of selectively growing the silicon epitaxial layer is conducted within a pressure range of approximately 1 to 200 Torr.

15. The method for forming a contact plug of a semiconductor device according to claim 10:
wherein the single crystal silicon portion has a height of approximately 500 Å.

16. The method for forming a contact plug of a semiconductor device according to claim 10:
wherein the step of growing the single crystal silicon portion is completed in approximately 30 to 60 seconds.

17. The method for forming a contact plug of a semiconductor device according to claim 10:
wherein the step of growing the polycrystalline or amorphous silicon is performed at a temperature of approximately 550 to 610° C.

18. A method for forming a contact plug of semiconductor device comprising, in sequence, the steps of:
preparing a silicon substrate;
forming an insulating layer on the silicon substrate;
forming a contact hole in the insulating layer to expose a portion of the silicon substrate;
dry cleaning the exposed portion of the silicon substrate;
wet cleaning the exposed portion of the silicon substrate;
inserting the silicon substrate into a LPCVD apparatus;
H₂ baking the exposed portion of the silicon substrate region;
selectively growing an epitaxial single crystal silicon portion on the exposed portion of the silicon substrate at a temperature of approximately 550 to 700° C.;
selectively growing a second epitaxial silicon portion on the epitaxial single crystal silicon portion, the second epitaxial silicon portion comprising polycrystalline silicon, amorphous silicon, or a combination thereof, at a temperature of approximately 550 to 700° C., the thickness of the second epitaxial silicon portion being sufficient to render the contact hole at least substantially filled; and
removing the silicon substrate from the LPCVD apparatus.

19. The method for forming a contact plug of a semiconductor device according to claim 18:
wherein the step of dry cleaning the exposed portion of the silicon substrate further comprises treating the silicon substrate a NF₃/O₂ plasma for approximately 20 to 30 seconds.

20. The method for forming a contact plug of a semiconductor device according to claim 18:
wherein the step of wet cleaning the exposed portion of the silicon substrate further comprises applying a mixed solution of BOE and H₂SO₄ to the silicon substrate for approximately 20 to 30 seconds.

21. The method for forming a contact plug of a semiconductor device according to claim 18:
wherein the step of H₂ baking further comprises treating the silicon substrate at a temperature of approximately 700 to 1,000° C. for approximately 60 to 300 seconds.

22. The method for forming a contact plug of a semiconductor device according to claim 18:
wherein the epitaxial single crystal silicon portion comprises a substantially conical or pyramidal structure grown on the exposed portion of the silicon substrate; and
the second epitaxial silicon portion is grown on an exposed surface of the epitaxial single crystal silicon and on a sidewall of the contact hole.
